(19) United States
(12) Patent Application Publication
(10) Pub. No.: US 2013/0226496 A1
(43) Pub. Date: Aug. 29, 2013

(54) PRECISE CALIBRATION OF ELECTRONIC COMPONENTS

(71) Applicants: Prasad S. Gudem, San Diego, CA (US); Bhushan Shanti Asuri, San Diego, CA (US); Li-Chung Chang, (US); Vinod V. Panikkath, (US)

(72) Inventors: Prasad S. Gudem, San Diego, CA (US); Bhushan Shanti Asuri, San Diego, CA (US); Li-Chung Chang, (US); Vinod V. Panikkath, (US)

(73) Assignee: QUALCOMM Incorporated, San Diego, CA (US)

(21) Appl. No.: 13/407,993

(22) Filed: Feb. 29, 2012

(51) Int. Cl. G01R 35/00; G06F 19/00

(52) U.S. Cl. 702/107

(57) ABSTRACT

A system for precise calibration of electronic components is disclosed. In an exemplary embodiment, an apparatus for calibrating a tunable component on an integrated circuit chip includes an on-chip reference component configured to generate a first on-chip reference level, an on-chip connector configured to couple to an external test unit component to generate a second on-chip reference level, and an on-chip memory configured to store at least one error adjustment parameter determined from a difference between the first on-chip reference level and the second on-chip reference level, and wherein the at least one error adjustment parameter is configured to calibrate the tunable component to a desired value.

### BACKGROUND

1. Field

The present application relates generally to the operation and design of electronic circuits, and more particularly, to calibration of electronic components.

2. Background

The performance of electronic devices may be adversely affected by parameter variations attributable to many sources. In this context, performance may relate to characteristics such as gain, noise figure, output power, and current or voltage accuracy. Some sources of performance variations are process variation, temperature, and power supply tolerance.

Reduction of performance variations may be achieved through component calibration. For example, a typical device includes a circuit board that comprises one or more electronic components, such as integrated circuit chips. It is possible to calibrate each of the chips to improve the overall performance of the device. Unfortunately, conventional approaches to minimize performance variation rely on additional circuit board components and/or device level calibration which are costly and use valuable board space. Therefore, it would be desirable to have a mechanism that can provide precise calibration of integrated circuit chips without adding additional circuit board components and associated calibration costs.

### BRIEF DESCRIPTION OF THE DRAWINGS

The foregoing aspects described herein will become more readily apparent by reference to the following description when taken in conjunction with the accompanying drawings wherein:

FIG. 1 shows an exemplary embodiment of a calibration module that is used to calibrate integrated circuits for installation in a production unit;

FIG. 2 shows an exemplary embodiment of an integrated circuit comprising an exemplary embodiment of a calibration module;

FIG. 3 shows an exemplary embodiment of the integrated circuit of FIG. 2 and illustrates a detailed view of the exemplary calibration module;

FIG. 4 shows an exemplary embodiment of a method for precise calibration of one or more tunable components in an integrated circuit;

FIG. 5 shows an exemplary integrated circuit configured as an RF receiver that comprises an exemplary embodiment of a calibration module;

FIG. 6 shows an exemplary integrated circuit configured as an RF transmitter that comprises an exemplary embodiment of a calibration module;

FIG. 7 shows an exemplary embodiment of a method for precise calibration of an integrated circuit;

FIG. 8 shows an exemplary lookup table;

FIG. 9 shows an exemplary production unit that includes an integrated circuit transceiver comprising an exemplary embodiment of the calibration module; and

FIG. 10 shows an exemplary apparatus configured for calibration of an integrated circuit.

### DETAILED DESCRIPTION

The detailed description set forth below in connection with the appended drawings is intended as a description of exemplary embodiments of the invention and is not intended to represent the only embodiments in which the invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well known structures and devices are shown in block diagram form in order to avoid obscuring the novelty of the exemplary embodiments presented herein.

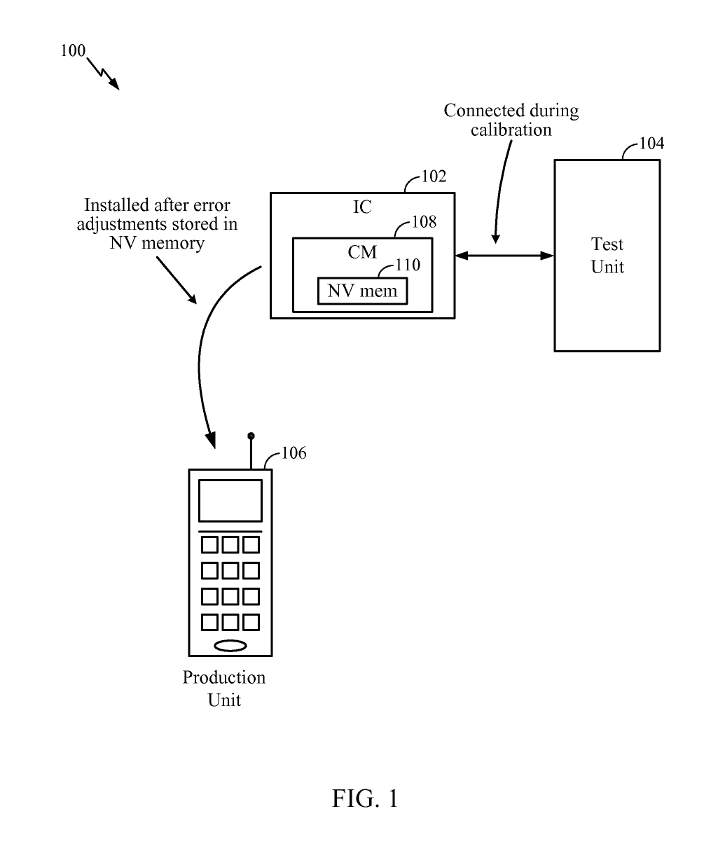

FIG. 1 shows an exemplary embodiment of a calibration module (CM) 108 that is used to calibrate an integrated circuit (IC) 102 for installation in a production unit 106. During a calibration process, the IC 102 is connected to a test unit 104 so that the calibration module 108 can perform various tests and calibrations. Error adjustments related to the operation of the IC 102 are determined during the calibration process and stored in non-volatile memory 110. For example, component tuning adjustments and input/output gain parameters are stored in the non-volatile memory 110. After calibration, the IC 102 is disconnected from the test unit 104 and installed in a production unit 106. For example, the production unit may be a wireless device, such as a cell phone, pager, or tablet. During power up or reset, the CM 108 of the IC 102 operates to acquire the error adjustments from the NV memory 110 and recalibrate the IC 102 in the production unit 106. Accordingly, board space and additional calibration circuitry in the production unit is not necessary, which provides substantial cost savings. A more detailed description of exemplary embodiments of the CM and its functions are provided below.

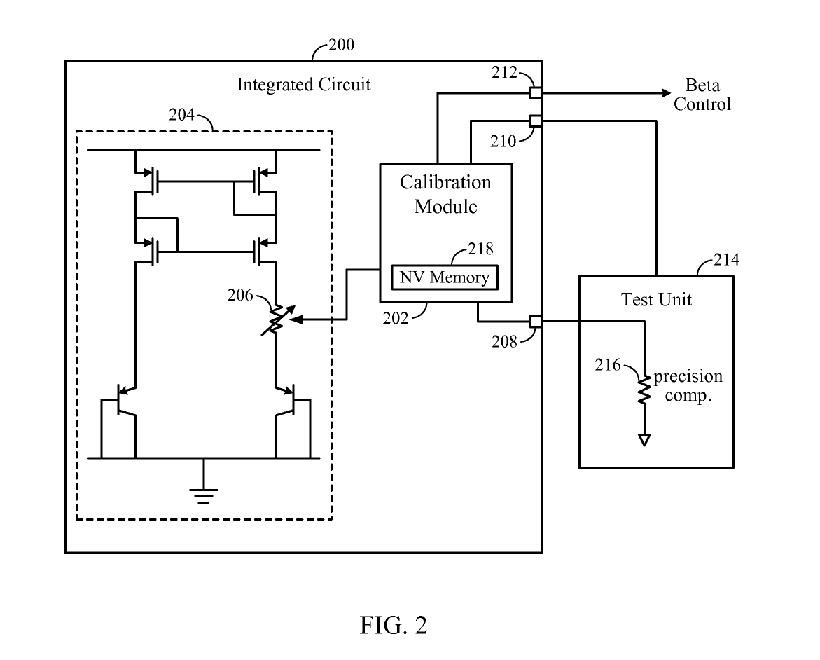

FIG. 2 shows an exemplary embodiment of an integrated circuit 200 comprising an exemplary embodiment of a calibration module 202. The integrated circuit 200 comprises a functional circuit 204 that operates to provide one or more desired functions using one or more functional elements. The functional circuit 204 comprises a tunable circuit component 206, which in this exemplary embodiment is a tunable resistor. The integrated circuit 200 also comprises the calibration module 202. The calibration module 202 operates to calibrate the tunable component 206. The IC 200 also comprises port pins 208, 210, and 212 that can be used to couple signals between the calibration module 202 and external devices. The port pin 210 provides communication with a test unit 214 and the port pin 212 is used to output a beta control signal. The port pins 210 and 212 are described in further detail below.

During a calibration mode, the test unit 214 comprises a precision component 216, such as precision resistor, that is connected to the port pin 208. The calibration module 202 performs a calibration procedure using the precision component 216 to generate a reference current. Using this reference current, the calibration module 202 is able to determine a precise setting for the tunable component 206. For example, the precise setting comprises an error adjustment to correct, for instance, a resistance error associated with the tunable component 206. The precise setting is stored in a NV memory 218 of the calibration module 202 and can be used to retune the tunable component 206 at any time, such as after a power up or circuit reset. Once the calibration module 202 determines the precise setting for the tunable component 206, the test unit 214 is no longer needed and can be disconnected from the IC 200. The IC 200 can then be installed in a production unit, such as the production unit 106 shown in FIG. 1.

Therefore, the calibration module 202 provides the following functions and advantages over conventional systems.
1. Avoids the use of precision components on the production unit 106, thereby saving component cost and board space. For example, the IC 200 may be mounted on a circuit board in a production unit 106 and the calibration module 202 operates to provide component calibration that avoids the use of precision components on this circuit board.
2. Utilizes an external test unit 214 to provide a precision component to perform a calibration procedure, and stores the calibration information in the NV memory 218 of the calibration module 202 after the calibration procedure is completed.
3. Saves costs and circuit space since precision components are provided only on test units (i.e., test unit 214), of which there may be only ten to a hundred units, thereby avoiding the use of precision components on every production unit 106, which may number in the millions.

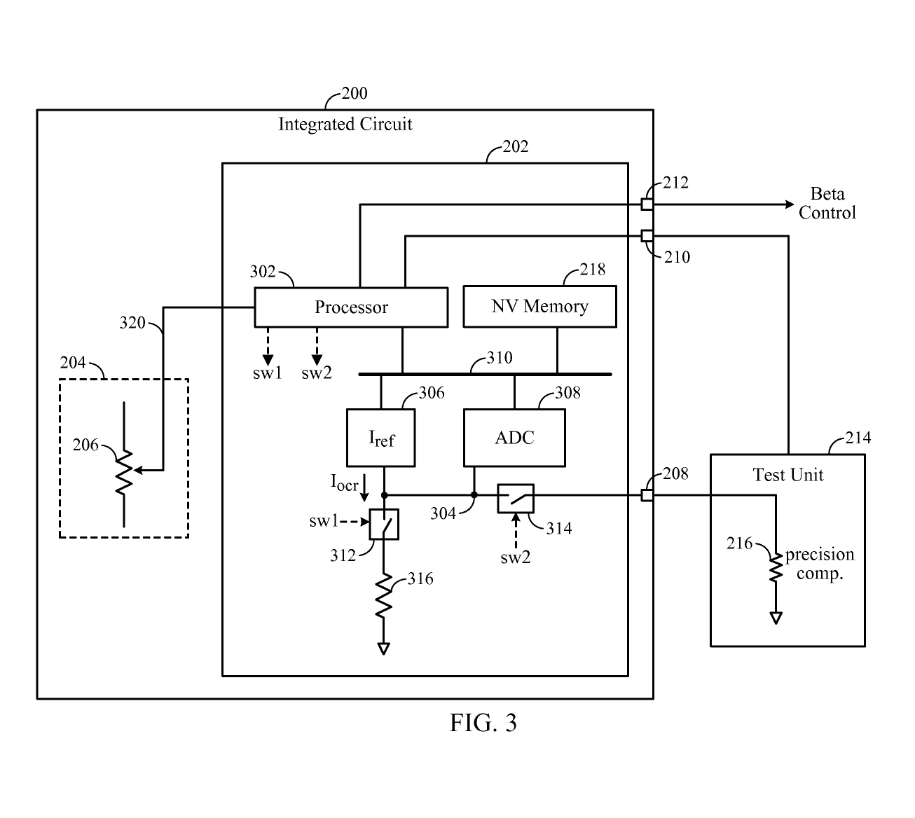

FIG. 3 shows an exemplary embodiment of the IC 200 and illustrates a detailed view of an exemplary embodiment of the calibration module 202. The calibration module 202 comprises processor 302, the non-volatile (NV) memory 218, current reference module 306, and analog to digital converter (ADC) 308 all coupled to communicate over bus 310. The calibration module 202 also comprises a first switch 312, a second switch 314, and an on-chip reference component 316.

The processor 302 comprises at least one of a CPU, processor, gate array, hardware logic, memory elements, and/or hardware executing software. The processor 302 operates to control the functional elements of the calibration module 202 to perform precise component calibration. For example, the processor 302 operates to generate switch control signals sw1 and sw2 that are used during a calibration process to precisely tune the tunable resistor 206.

The processor 302 is also configured to communicate with the external test unit 214 using the port pin 210 and to output a beta control signal using the port pin 212. Thus, the processor 302 can exchange information with external devices and can receive information that can be stored in the NV memory 218.

The NV memory 218 comprises EEPROM or any other suitable NV storage device operable to allow the storage and retrieval of information during operation of the calibration module 202. The NV memory 218 retains information stored in it even during power down intervals. In an exemplary embodiment, the NV memory 218 stores a look up table (LUT) that comprises parameters used for calibration and operation of the IC 200. The NV memory 218 also operates to store (or embody) instructions or codes executable by the processor 302 to perform the calibration functions described herein.

The current reference module 306 operates to output an on-chip reference current (I_{OCR}) for use during a calibration procedure. For example, in an exemplary embodiment, the current reference module comprises a bandgap circuit configured to generate a precise bandgap voltage. The current reference module 306 also comprises one or more resistors and/or other components configured to use the precise bandgap voltage to generate the on-chip reference current (I_{ocr}). It should also be noted and any other suitable technique may be used to generate the on-chip reference current (I_{ocr}).

The ADC 308 comprises any suitable analog to digital converter that operates to measure an analog voltage and generate a corresponding digital value. In an exemplary embodiment, the ADC 308 is configured to measure a voltage level at terminal 304.

The on-chip reference component 316 is a component has a value similar to the precision component 216 in the test unit 214. For example, in this exemplary embodiment, the on-chip reference component 316 is a fixed resistor having a resistance value in the range of the precision component 216. Since the on-chip reference component 316 and the tunable component 206 are both formed on the IC 200 (i.e., on the same die) the two components will have similar performance characteristics. Thus, determining the performance characteristics (i.e., resistance value) of the on-chip reference component 316 will also determine the performance characteristics of the tunable component 206.

During operation in a calibration mode, the processor 302 generates the switch control signals (sw1 and sw2) so that switch 312 is closed and switch 314 is open. The processor 302 controls the current reference module 306 to output the on-chip reference current I_{ocr} that passes through switch 312 and the on-chip reference component 316. The processor 302 controls the ADC 308 to measure the voltage level at the terminal 304 and store the measured voltage level in the NV memory 218.

The processor 302 then generates the switch control signals (sw1 and sw2) so that switch 312 is open and switch 314 is closed. The processor 302 controls the current reference module 306 to output the on-chip reference current I_{ocr} that passes through the switch 314 and the port pin 208 to the precision component 216 in the test unit 214. The processor 302 controls the ADC 308 to measure the voltage level at the terminal 304 and store the measured voltage level in the NV memory 218.

The processor 302 then retrieves and compares the two measured voltage levels from the NV memory 218 and determines performance differences between the on-chip reference component 316 and the precision component 216 of the test unit 214. The performance differences are used to determine error adjustment parameters to adjust the tunable component 206 to a precise setting. For example, precise error adjustments for tuning of the resistance value of the tunable resistor 206 can be determined. The processor 302 stores the precise setting (error adjustments) for the tunable component 206 in the NV memory 218 and outputs a corresponding control signal 320 that precisely tunes the tunable component 206.

After the calibration procedure, the test unit 214 including the precision external component is disconnected from the IC 200 and the processor 302 can retune the tunable component 106 at any time using the precise setting (error adjustment) stored in the NV memory 218. It should be noted that although described with reference to a tunable resistor, the calibration module 202 can operate in a similar fashion to precise set other types of components, such as capacitors, inductors or other component types, and any number of such components.

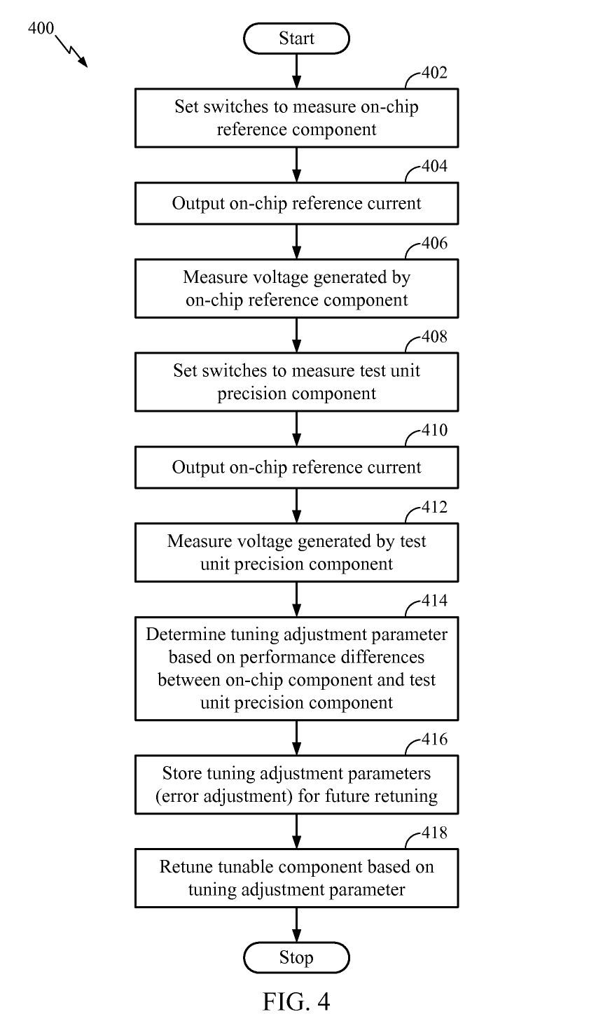

FIG. 4 shows an exemplary embodiment of a method 400 for precise calibration of one or more tunable components on an integrated circuit. For example, the method is suitable for use by the calibration module 202 shown in FIG. 3. In an exemplary embodiment, the processor 302 executes one or more sets of codes stored in the NV memory 218 to control the calibration module 202 to perform the functions described below.

At block 402, switches are set to measure characteristics of an on-chip reference component. For example, the processor 302 outputs the switch control signals sw1 and sw2 to close switch 312 and open switch 314 so that characteristics of the on-chip resistor 316 can be measured.

At block 404, an on-chip reference current is generated. For example, the current reference module 306 generates an on-chip reference current I_{ocr} based on a bandgap voltage and an internal resistor. The on-chip reference current I_{ocr} flows through the switch 312 to the on-chip resistor 316.

At block 406, the voltage generated by the on-chip reference component is measured. For example, the ADC 308 measures the voltage at terminal 304, which represents the voltage generated by the on-chip reference resistor 316 in response to the reference current I_{ocr}. The measured voltage is stored in the NV memory 218.

At block 408, switches are set to measure characteristics of a precision component on a test unit. For example, the processor 302 outputs the switch control signals sw1 and sw2 to open switch 312 and close switch 314 so that characteristics of the precision reference resistor 216 of the test unit 214 can be measured.

At block 410, an on-chip reference current is generated. For example, the current reference module 306 generates an on-chip reference current I_{ocr} based on a bandgap voltage and an internal resistor. The on-chip reference current I_{ocr} flows through the switch 314 to the precision reference resistor 216 on the test unit 214.

At block 412, the voltage generated by the precision reference component is measured. For example, the ADC 308 measures the voltage at terminal 304, which represents the voltage generated by the precision reference resistor 216 on the test unit 214 in response to the reference current I_{ocr}. The measured voltage is stored in the NV memory 218.

At block 414, a tuning adjustment parameter (error adjustment) is determined based on the measured characteristics of the on-chip reference component 316 and the precision reference component 216 of the test unit 214. For example, the processor 302 determines the tuning adjustment parameter as a digital adjustment value based on a difference between the measured voltages generated by the on-chip resistor 316 and the precision resistor 216 on the test unit 214.

At block 416, the tuning adjustment parameter is stored in memory. For example, the tuning adjustment parameter is stored in the NV memory 218.

At block 418, a tunable component on the IC is tuned using the tuning adjustment parameter stored in memory. For example, the processor 302 retrieves the tuning adjustment parameter (error adjustment) from the memory 218 and tunes the tunable component 206 using the control line 320. Thus, the resistance value of the tunable resistor 206 is tuned to a precise value.

Therefore, the method 400 can be performed by an on-chip calibration module to tune tunable on-chip components. It should be noted that the method 400 is just one implementation and that the operations of the method 400 may be rearranged or otherwise modified within the scope of the various exemplary embodiments. Thus, other implementations are possible.

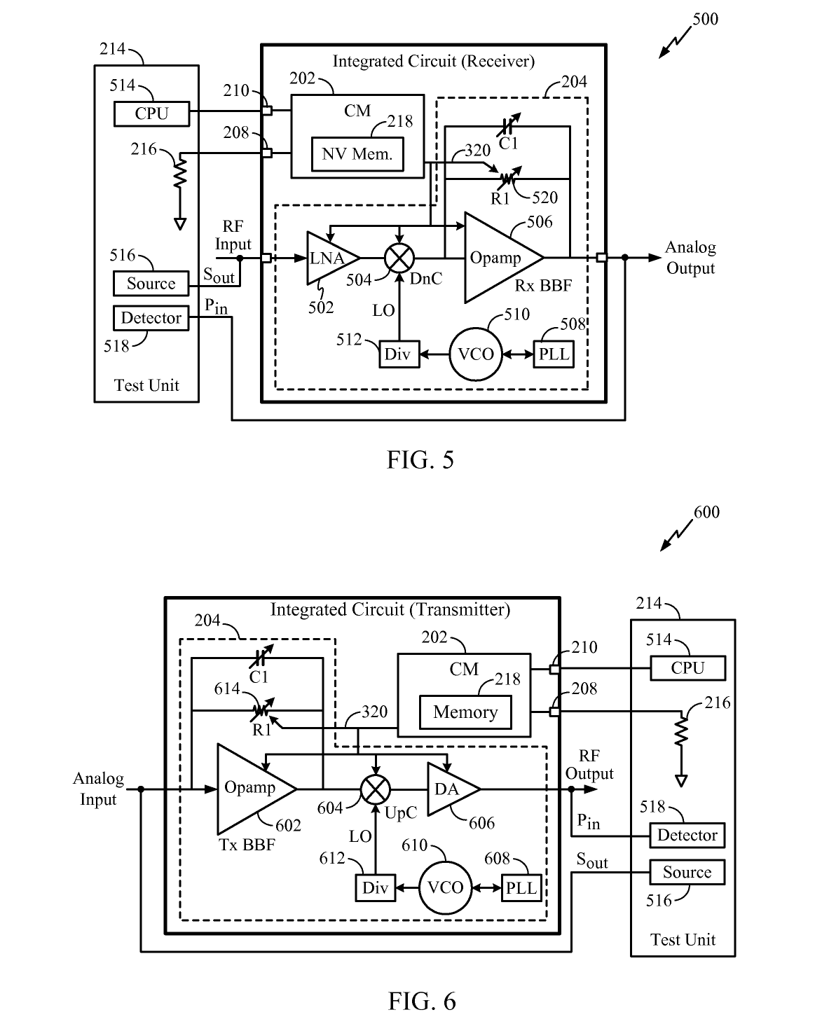

FIG. 5 shows an exemplary integrated circuit 500 configured as an RF receiver that comprises an exemplary embodiment of the calibration module 202. For example, the integrated circuit 500 may be used in a wireless device to provide RF signal reception. The integrated circuit 500 includes functional circuitry 204 that comprises a low noise amplifier (LNA) 502 that receives an RF input signal and passes an amplified version of the RF input signal to a downconverter (DnC) 504. A phase locked loop 508, voltage controlled oscillator (VCO) 510 and frequency divider 512 operate together to generate a local oscillator (LO) signal that is also input to the downconverter 504. The output of the downconverter 504 is passed to an Rx baseband filter comprising opamp 506, capacitor C1 and tunable resistor R1 520. The opamp 506 outputs a filtered analog output signal.

In an exemplary embodiment, the calibration module 202 is constructed and operates according to the description with reference to FIG. 3. During a component calibration process, the test unit 214 is coupled to the integrated circuit 500 so that the precision external component 216 is coupled to port pin 208. The calibration module 202 uses the precision component 216 to determine precise tuning parameters (error adjustments) to tune the tunable resistor R1 520. For example, the calibration module 202 comprises an internal on-chip reference component (i.e., component 316 as shown in FIG. 3), whose performance is compared to the precision component 216 (as described with reference to FIG. 3). The comparison is used to determine the precise tuning parameters (error adjustments) that are used to precisely tune the tunable resistor R1 520 using the control signal 320.

In a circuit calibration process, input/output characteristics of the integrated circuit 500 are calibrated. In this mode, the test unit 214 comprises a central processing unit (CPU) 514, signal source 516, and detector 518. The signal source 516 is coupled to input a signal into the RF input of the integrated circuit 500. The detector 518 is coupled to receive the analog output of the integrated circuit 500 and determine detected power levels.

The calibration module 202 is also configured to control operating characteristics of the LNA 502, DnC 504, and opamp 506 using the control signal 320. For example, the gain and/or other operating characteristics of the LNA 502, DnC 504, and amplifier 506 can be set by the calibration module 202. In an exemplary embodiment, the operating parameters are stored in the NV memory 218 and these operating parameters are used to set the operation of the LNA 502, DnC 504, and opamp 506. In another embodiment, the operating parameter are received by the calibration module 202 from another entity (such as the test unit 214) and stored in the NV memory 218 for later use.

During the circuit calibration process, the CPU 514 controls the signal source 516 to output a desired test signal that is input to the RF input of the integrated circuit 500. The CPU 514 then signals the calibration module 202 through the port pin 210 to use selected operating parameters to set the operation of the LNA 502, DnC 504, and opamp 506. For example, the gains associated with these functional blocks are set by the calibration module 202. The CPU 514 controls the detector 518 to detect the output power level at the analog output of the integrated circuit 500. This process is repeated for other input power levels to allow the input and output performance of the integrated circuit 500 be determined for various input and output power levels. The CPU 514 determines any error adjustments or compensation parameters and communicates these results through the port pin 210 to the calibration module 202 for storage in the NV memory 218. For example, the input/output calibration parameters are stored in a lookup table in the NV memory 218. Thus, the overall input/output performance of the integrated circuit 500 is stored in the integrated circuit itself and can be retrieved at any time.

After the component and unit calibration procedures, the test unit 214 is disconnected from the integrated circuit 500 and the calibration module 202 can retune the tunable component R1 520 at any time using the precise settings stored in the NV memory 218 of the calibration module 202. The calibration module 202 can also output correction parameters to compensate for errors determined during the circuit calibration process. For example, the calibration module 202 can retrieve error adjustment and/or compensation vales from the NV memory 218 and load these into the functional components 502, 504, and 506 of the circuit 204. It should be noted that although described with reference to one tunable resistor, the calibration module 202 can be configured to precisely tune any number of tunable components on the integrated circuit 500.

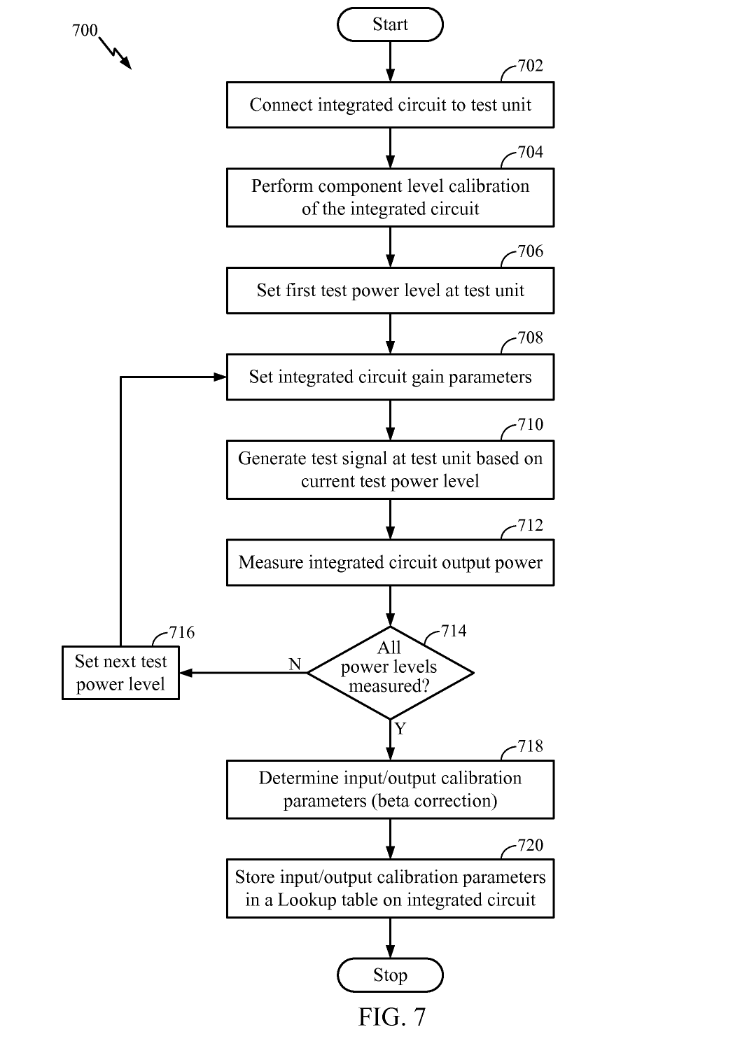

FIG. 6 shows an exemplary integrated circuit 600 configured as an RF transmitter that comprises an exemplary embodiment of the calibration module 202. For example, the integrated circuit 600 may be used in a wireless device to provide RF signal transmission. The integrated circuit 600 comprises functional circuitry 204 that includes a Tx baseband filter comprising an opamp 602 coupled to capacitor C1 and tunable resistor R1 614. The opamp 602 receives an analog input signal and passes a filtered version of the analog input signal to an upconverter 604. A phase locked loop 608, VCO 610 and frequency divider 612 operate together to generate a local oscillator (LO) signal that is also input to the upconverter 604. The output of the upconverter 604 is passed to a driver amplifier 606 that outputs an RF output signal.

In an exemplary embodiment, the calibration module 202 is constructed and operates according to the description with reference to FIG. 3. During a component calibration process, the test unit 214 is coupled to the integrated circuit 600 so that the precision external component 216 is coupled to port pin 208. The calibration module 202 uses the precision component 216 to determine precise tuning parameters (error adjustments) to tune the tunable resistor R1 614. For example, the calibration module 202 performs the method 400 wherein performance of an on-chip reference component 316 (as shown in FIG. 3), is compared to the precision component 216 of the test unit 214. The comparison is used to determine the precise tuning parameters that are used to precisely tune the tunable resistor R1 614.

In a circuit calibration process, input/output characteristics of the integrated circuit 600 are calibrated. The signal source 516 is coupled to input a signal into the analog input of the integrated circuit 600. The detector 518 is coupled to receive the RF output of the integrated circuit 600 and determine detected power levels.

The calibration module 202 is also configured to control operating characteristics of the opamp 602, UpC 604, and driver 606 using the control signal 320. For example, the gain and/or other operating characteristics of the opamp 602, UpC 604, and driver 606 can be set by the calibration module 202. In an exemplary embodiment, the operating parameters are stored in the NV memory 218 and these operating parameters are used to set the operation of the opamp 602, UpC 604, and driver 606. In another exemplary embodiment, the operating parameter are received by the calibration module 202 from another entity (such as the test unit 214) and stored in the NV memory 218 for later use.

During the circuit calibration process, the CPU 514 controls the signal source 516 to output a desired test signal that is input to the analog input of the integrated circuit 600. The CPU 514 then signals the calibration module 202 through the port pin 210 to use selected operating parameters to set the operation of the opamp 602, UpC 604, and driver 606. For example, the gain of these functional components can be set by the calibration module 202. The CPU 514 controls the detector 518 to detect the output power level at the RF output of the integrated circuit 600. This process is repeated to allow the input and output performance of the integrated circuit 600 to be determined for various input and output power levels. The CPU 514 then determines error adjustments or compensation values and communicates these results through the port pin 210 to the calibration module 202 for storage in the NV memory 218. Thus, the overall input/output performance of the integrated circuit 600 is stored in a lookup table on the integrated circuit itself and can be retrieved at any time.

After the component and circuit calibration procedures, the test unit 214 is disconnected from the integrated circuit 600 and the calibration module 202 can retune the tunable component R1 614 at any time using the precise settings stored in the NV memory 218 of the calibration module 202. The calibration module 202 can also output correction parameters to compensate for errors determined during the circuit calibration process. It should be noted that although described with reference to one tunable resistor, the calibration module 202 can be configured to precisely tune any number of tunable components on the integrated circuit 600.

FIG. 7 shows an exemplary embodiment of a method 700 for precise calibration of an integrated circuit. For example, the method is suitable for use with the integrated circuit 600 shown in FIG. 6. In an exemplary embodiment, the processor 202 executes one or more sets of codes stored in the NV memory 218 to control the calibration module 202 to perform the functions described below.

At block 702, an integrated circuit is connected to a test unit. For example, the integrated circuit 600 is connected to the test unit 214 as illustrated in FIG. 6.

At block 704, component level fine tuning of on-chip tunable components is performed. For example, the calibration module 202 performs on-chip fine tuning of tunable components associated with the opamp 602, UpC 604, and/or driver 606. In an exemplary embodiment, the fine tuning is performed using the method 400 shown in FIG. 4.

At block 706, circuit level calibration begins. In an exemplary embodiment, the CPU 514 determines a first test power level.

At block 708, gain parameters of the integrated circuit are set. In an exemplary embodiment, the CPU 514 signals the calibration module 202 through the port pin 210 to indicate which gain parameters are to be used. The calibration module 202 sets the gain of the opamp 602, UpC 604, and driver amplifier 606 based on the selected gain parameters stored in the memory 218.

At block 710, a test signal is generated based on the current test power level. For example, the signal source 516 outputs a test signal at the current test power level. The signal is input the analog input of the opamp 602.

At block 712, the output power of the integrated circuit is measured. For example, in response to the current gain settings and input power level, the detector 518 measures the RF output power of the integrated circuit 600.

At block 714, a determination is made as to whether all desired input power levels have been tested. For example, the CPU 514 makes this determination. If more input power levels need to be tested, the method proceeds to block 716. If all desired input power levels have been tested, the method proceeds to block 718.

At block 716, the current test power level is set to the next level. For example, the CPU 514 determines the new current test power level and the method proceeds to block 708.

At block 718, input/output calibration parameters for the integrated circuit are determined. For example, the CPU 514 determines the overall input/output parameters for the integrated 600. The overall parameters include a beta adjustment, which indicates errors between an ideal output power level and a measured output power level.

At block 720, the input/output calibration parameters and beta adjustment are stored at the calibration module. For example, a lookup table comprising all the parameters and beta values is stored in the NV memory 218 of the calibration module 202.

Therefore, the method 700 can be performed on an integrated circuit comprising a calibration module to calibrate components or overall input/output characteristics. It should be noted that the method 700 is just one implementation and that the operations of the method 700 may be rearranged or otherwise modified within the scope of the various implementations. Thus, other implementations are possible.

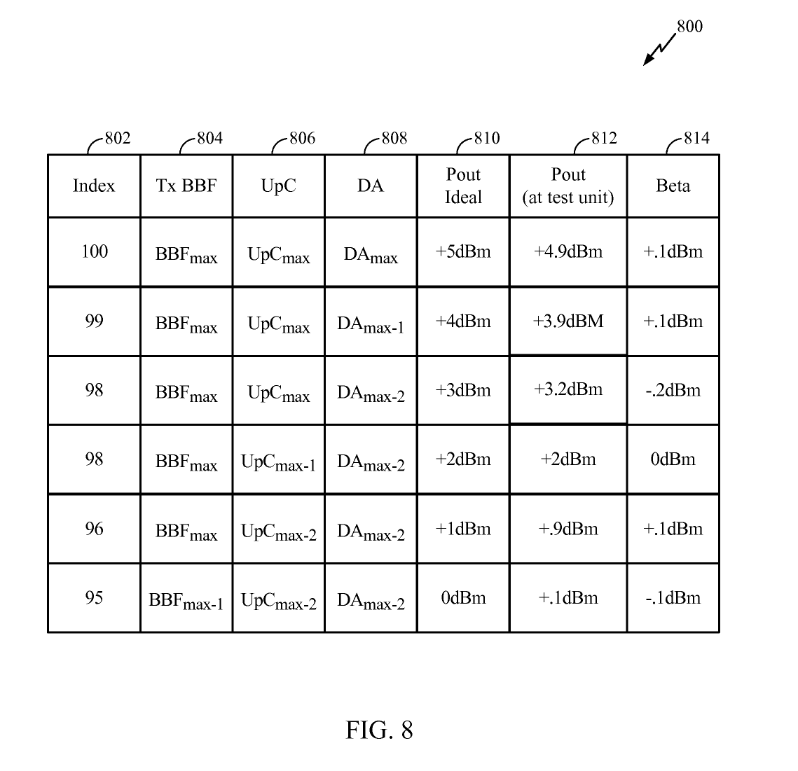

FIG. 8 shows an exemplary embodiment of a look up table (LUT) 800. For example, the LUT 800 is stored in the memory 218 of the calibration module 202 during calibration of the input/output parameters of the integrated circuit 600, as described with reference to FIG. 7. It should be noted that it is also possible to generate a similar look up table for the input/output parameters of the integrated circuit 500 shown in FIG. 5. The LUT 800 comprises columns of functional block settings that can be used to obtain a selected power output. For example, the LUT 800 comprises an index column 802, filter gain column 804, UpC gain column 806, driver amp gain column 808, ideal power output (Pout) column 810, measured Pout column 812, and beta (error correction) column 814.

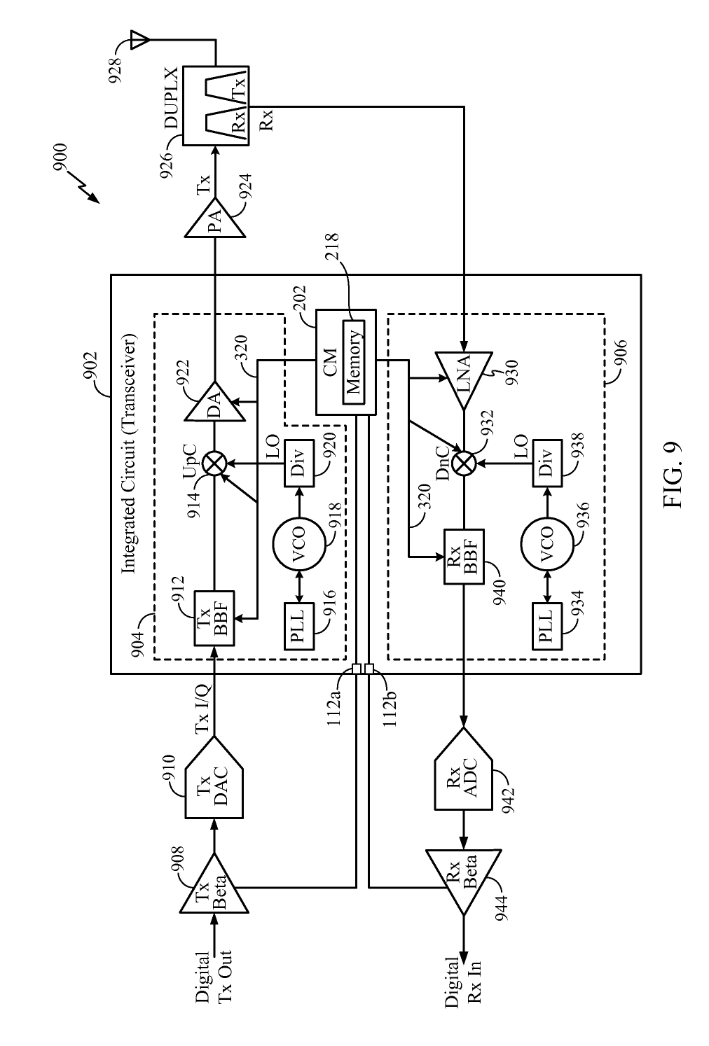

The lookup table 800 can be used during operation of the device 600 to set the operation of the opamp 602, UpC 604, and DA 606 to achieve a selected power output indicated in the Pout column 802. To correct for errors or deviations from the desired output power, the calibration module 202 outputs parameters in the beta column 814 to set a beta amplifier (shown in FIG. 9) to correct for any such errors or deviations. Therefore, after the test unit 214 is has performed both component calibration and circuit calibration, the NV memory 218 of the calibration module 202 comprises all the parameters necessary to precisely tune the integrated circuit.

FIG. 9 shows an exemplary device 900 comprising an integrated circuit 902 configured as a transceiver that comprises an exemplary embodiment of the calibration module 202. For example, the device 900 may be a wireless device that operates to provide wireless communications with other devices. The integrated circuit 902 comprises a transmitter section 904 and a receiver section 906 that are coupled to additional external components to provide transmit and receive signal paths. For example, a digital Tx out signal is received by a Tx beta amplifier 908 that passes an amplified version of the digital signal to a transmit digital to analog (DAC) converter 910. The analog output of the DAC 910 is input to a baseband filter 912 of the integrated circuit 902 that filters the signal it receives and generates a filtered output signal that is input to an upconverter 914. A PLL 916, VCO 918 and frequency divider 920 are coupled together to generate an Tx LO signal that is also input to the upconverter 914. The output of the upconverter 914 is input to a driver amplifier 920 that outputs an amplified signal that is input to a power amplifier (PA) 922. The PA 922 amplifies the signal it receives and outputs an amplified signal to a duplexer 926 that passes a filtered signal to antenna 928 for transmission.

Similarly, a signal received by the antenna 928 is filtered by the duplexer 926 and input to an LNA 930 of the integrated circuit 902. The output of the LNA 930 is input to a downconverter (DnC) 932. A PLL 934, VCO 936 and frequency divider 938 are coupled together to generate an Rx LO signal that is also input to the downconverter 932. The output of the downconverter 932 is input to an amplifier 940 that outputs an amplified signal to an analog to digital converter (ADC) 942. The digital output of the ADC 942 is input to an Rx beta amplifier (PA) 944, which outputs an amplified digital received signal.

### Tunable Component Calibration

It will be assumed that the Tx BBF 912, UpC 914, DA 922, LNA 930, DnC 932 and Rx BBF 940 all comprise tunable components, such as tunable resistors, for which a calibration procedure can been performed so that the NV memory 218 comprises tuning parameters that can be used to precisely tune these tunable components. For example, the precise tuning parameters for each tunable component can be determined using the method 400 shown in FIG. 4.

At power up or after a reset condition, the calibration module 202 accesses the memory NV 218 to acquire the precision tuning parameters (error adjustments). The processor 202 is able to tune each of the components using the control signal 320. For example, at power up, the processor 202 accesses the memory 218 acquires the tuning value for a tunable resistor associate with the Tx BBF 912 and outputs the digital tuning value using the control line 320 to program the tunable resistor for this functional element. A similar process is performed for other tunable components in the integrated circuit 902.

### Overall Circuit Calibration

It will further be assumed that the input/output characteristics of the transmitter section 904 and the receiver section 906 have been calibrated using the calibration method 700 describe with reference to FIG. 7. Therefore, the NV memory 218 also comprises input/output calibration parameters in a LUT that can be used to precisely calibrate the input/output characteristics of the transmitter section 904 and the receiver section 906. For example, the NV memory 218 comprises a look up table similar to the LUT 800 as shown in FIG. 8.

During operation, the calibration module 202 accesses the memory NV 218 to acquire the beta correction parameters based on the current input/output power information. In an exemplary embodiment, the calibration module 202 acquires the current input/output power information from another entity at the device 900. Base on the current transmit power, the calibration module 202 obtains the appropriate beta correction factor from the LUT in the memory 218 and outputs this correction factor using the port pin 112a to program the Tx beta amplifier 908 to correct for input/output errors of the transmitter section 904 of the integrated circuit 902. Similarly, based on the current receive power, the calibration module 202 obtains the appropriate beta correction factor from the LUT in the memory 218 and outputs this correction factor using the port pin 112b to program the Rx beta amplifier 944 to correct for input/output errors of the receiver section 906 of the integrated circuit 902. Thus, the LUT in the memory 204 is utilized to calibrate both the transceiver section 904 and the receiver section 906 based on current power requirements.

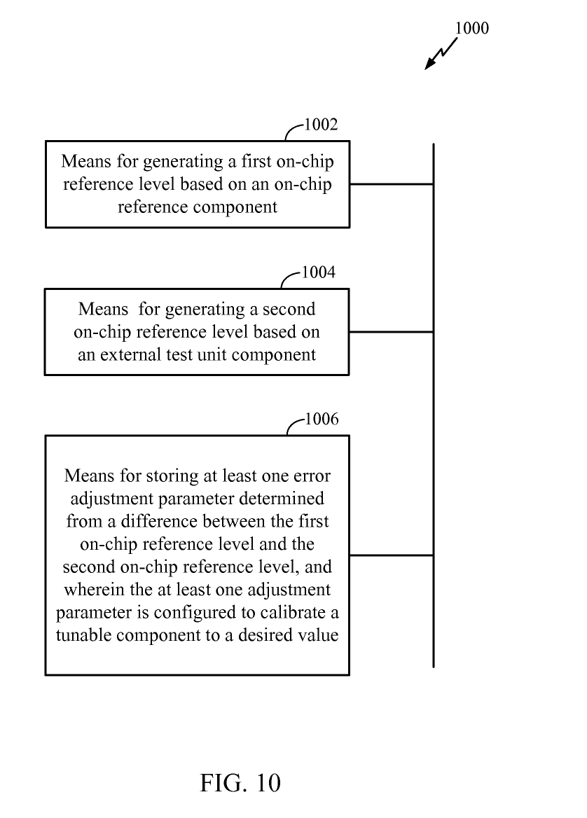

FIG. 10 shows an exemplary calibration apparatus 1000. The apparatus 1000 is suitable for use as the calibration module 202 shown in FIG. 3. In an exemplary embodiment, the apparatus 1000 is implemented by one or more modules configured to provide the functions as described herein. For example, in an aspect, each module comprises hardware and/or hardware executing software.

The apparatus 1000 comprises a first module comprising means (1002) for generating a first on-chip reference level based on an on-chip reference component, which in an aspect comprise the reference component 316.

The apparatus 1000 comprises a second module comprising means (1004) for generating a second on-chip reference level based on an external test unit component, which in an aspect comprises the port pin 208.

The apparatus 1000 comprises a third module comprising means (1006) for storing at least one error adjustment parameter determined from a difference between the first on-chip reference level and the second on-chip reference level, and wherein the at least one adjustment parameter is configured to calibrate a tunable component to a desired value, which in an aspect comprises the NV memory 218.

Those of skill in the art would understand that information and signals may be represented or processed using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. It is further noted that transistor types and technologies may be substituted, rearranged or otherwise modified to achieve the same results. For example, circuits shown utilizing PMOS transistors may be modified to use NMOS transistors and vice versa. Thus, the amplifiers disclosed herein may be realized using a variety of transistor types and technologies and are not limited to those transistor types and technologies illustrated in the Drawings. For example, transistors types such as BJT, GaAs, MOSFET or any other transistor technology may be used.

Those of skill would further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both non-transitory computer storage media and communication media including any medium that facilitates transfer of a computer program from one place to another. A non-transitory storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The description of the disclosed exemplary embodiments is provided to enable any person skilled in the art to make or use the invention. Various modifications to these exemplary embodiments will be readily apparent to those skilled in the art, and the generic principles defined herein may be applied to other embodiments without departing from the spirit or scope of the invention. Thus, the invention is not intended to be limited to the exemplary embodiments shown herein but is to be accorded the widest scope consistent with the principles and novel features disclosed herein.

What is claimed is:

1. An apparatus for calibrating a tunable component on an integrated circuit chip, comprising:
an on-chip reference component configured to generate a first on-chip reference level;
an on-chip connector configured to couple to an external test unit component to generate a second on-chip reference level; and
an on-chip memory configured to store at least one error adjustment parameter determined from a difference between the first on-chip reference level and the second on-chip reference level, and wherein the at least one adjustment parameter is configured to calibrate the tunable component to a desired value.

2. The apparatus of claim 1, further comprising a current reference module configured to generate an on-chip reference current that is used to determine the first and second on-chip reference levels.

3. The apparatus of claim 2, further comprising at least one switch configured to coupled to the on-chip reference current to the first on-chip reference component to generate the first on-chip reference level, and to couple the on-chip reference current to the external test unit component to generate the second on-chip reference level.

4. The apparatus of claim 3, further comprising a processor configured to control the operation of the at least one switch to determine the first and second on-chip reference levels and to determine the at least one error adjustment parameter from the first and second on-chip reference levels.

5. The apparatus of claim 4, the processor configured to acquire the at least one error adjustment parameter from the memory and use it to calibrate the tunable component to the desired value during power up or reset operations.

6. The apparatus of claim 1, further comprising an analog to digital converter configured to determine the first and second on-chip reference levels.

7. The apparatus of claim 1, wherein the external test unit component comprises a precision value and the on-chip reference component comprises a value approximately equal to the precision value.

8. An apparatus for calibrating a tunable component on an integrated circuit chip, comprising:
means for generating a first on-chip reference level based on an on-chip reference component;
means for generating a second on-chip reference level based on an external test unit component; and
means for storing at least one error adjustment parameter determined from a difference between the first on-chip reference level and the second on-chip reference level, and wherein the at least one adjustment parameter is configured to calibrate the tunable component to a desired value.

9. The apparatus of claim 8, further comprising means for generating an on-chip reference current that is used to determine the first and second on-chip reference levels.

10. The apparatus of claim 9, further comprising:
means for coupling the on-chip reference current to the first on-chip reference component to generate the first on-chip reference level; and
means for coupling the on-chip reference current to the external test unit component to generate the second on-chip reference level.

11. The apparatus of claim 10, further comprising:
means for acquiring the at least one error adjustment parameter; and
means for using the at least one error adjustment parameter to calibrate the tunable component to the desired value during power up or reset operations.

12. The apparatus of claim 8, wherein the external test unit component comprises a precision value and the on-chip reference component comprises a value approximately equal to the precision value.

13. A method for calibrating a tunable component on an integrated circuit chip, the method comprising:
generating a first on-chip reference level based on an on-chip reference component;
generating a second on-chip reference level based on an external test unit component to; and
storing in an on-chip memory at least one error adjustment parameter determined from a difference between the first on-chip reference level and the second on-chip reference level, and wherein the at least one adjustment parameter is configured to calibrate the tunable component to a desired value.

14. The method of claim 13, further comprising generating an on-chip reference current that is used to determine the first and second on-chip reference levels.

15. The method of claim 14, further comprising:
coupling the on-chip reference current to the first on-chip reference component to generate the first on-chip reference level; and
coupling the on-chip reference current to the external test unit component to generate the second on-chip reference level.

16. The method of claim 13, further comprising:
acquiring the at least one error adjustment parameter from the memory; and
using the at least one error adjustment parameter to calibrate the tunable component to the desired value during power up or reset operations.

17. An apparatus for calibrating an integrated circuit chip comprising at least one functional element, the apparatus comprising:
an on-chip memory comprising at least one correction factor associated with the at least one functional element, respectively; and
a processor configured to:
determine a power level associated with a current operating condition;
retrieve from the memory selected correction factors based on the power level; and
adjust the at least one functional element using the selected correction factors.

18. The apparatus of claim 17, the at least one functional element comprising a beta amplifier configured to adjust at least one of input power and output power, the processor configured to:
retrieve from the on-chip memory a beta adjustment factor based on the power level; and
adjust the beta amplifier based on the beta adjustment factor.

19. A method for calibrating an integrated circuit chip comprising at least one functional element, the method comprising:
storing in an on-chip memory at least one correction factor associated with the at least one functional elements, respectively;
determining a power level associated with a current operating condition;
retrieving from the on-chip memory selected correction factors based on the power level; and
adjusting the at least one functional element using the selected correction factors.

20. The method of claim 19, the at least one functional element comprising a beta amplifier configured to adjust at least one of input power and output power, the method further comprising:
retrieving from the on-chip memory a beta adjustment factor based on the power level; and
adjusting the beta amplifier based on the beta adjustment factor.
